(19) United States
(12) Patent Application Publication
(10) Pub. No.: US 2018/0046000 A1
(43) Pub. Date: Feb. 15, 2018

(54) ARRAY SUBSTRATE, LIQUID CRYSTAL DISPLAY DEVICE AND DRIVE METHOD OF LIQUID CRYSTAL DISPLAY DEVICE

(71) Applicant: Shenzhen China Star Optoelectronics Technology Co., Ltd., Shenzhen, Guangdong (CN)

(72) Inventor: Xiangyang XU, Shenzhen, Guangdong (CN)

(73) Assignee: Shenzhen China Star Optoelectronics Technology Co., Ltd., Shenzhen, Guangdong (CN)

(21) Appl. No.: 15/033,639

(22) PCT Filed: Mar. 3, 2016
(86) PCT No.: PCT/CN2016/075477

§ 371 Date: Apr. 30, 2016

(30) Foreign Application Priority Data
Feb. 18, 2016 (CN) 201610091227.0

(51) Int. Cl. G02F 1/1343; H01L 27/12; G02F 1/1362

(52) U.S. Cl. CPC G02F 1/1343; G02F 1/136286; H01L 27/1214; G09G 2320/0247

(57) ABSTRACT

The present invention discloses an array substrate, comprising a substrate, and two scan lines, a data line and a common electrode line located on the substrate, wherein the scan lines and the data line, the common electrode line are located to be isolated and intersect, and form a pixel unit, and the pixel unit comprises a pixel electrode, a common electrode, a first thin film transistor and a second thin film transistor, and both a gate of the first thin film transistor and a gate of the second thin film transistor are coupled to the scan line, and a source of the first thin film transistor is coupled to the data line, and a drain is coupled to the pixel electrode, and a source of the second thin film transistor is coupled to the common electrode line, and a drain is coupled to common electrode.

### CROSS REFERENCE

This application claims the priority of Chinese Patent Application No. 201610091227.0, entitled “Array substrate, liquid crystal display device and drive method of liquid crystal display device”, filed on Feb. 18, 2016, the disclosure of which is incorporated herein by reference in its entirety.

### FIELD OF THE INVENTION

The present invention relates to a display skill field, and more particularly to an array substrate, a liquid crystal display device having the array substrate and a drive method of a liquid crystal display device.

### BACKGROUND OF THE INVENTION

The liquid crystal display device of In-Plane Switching (IPS) mode is the liquid crystal display device which utilizes the electrical filed roughly parallel with the surface of the array substrate to make the liquid crystal molecules respond along the In-Plane direction. With the excellent view angle property, it has been used in the display application of respective fields. In the liquid crystal display device of IPS mode, the parallel electrical field generated by the edges of the pixel electrode and the common electrode and the vertical electrical field generated between the pixel electrode and the common electrode forms a multi-dimensional electrical field. Then, all the aligned liquid crystal molecules among the pixel electrodes, or among the common electrodes in the cell, right above the pixel electrodes or the common electrodes can generate rotation and conversion. Accordingly, the working efficiency of the plane orientated liquid crystal can be promoted and the transmission efficiency can be increased. In the IPS mode, the pixel electrode or the common electrode is generally located on the array substrate. Thus, the quality of the array substrate is the key of the product yield of the liquid crystal display device.

In prior art, the array substrate generally comprises a plurality of scan lines and a plurality of data lines. The plurality of scan lines and the plurality of data lines intersect in vertical and horizontal intersection to form a plurality of pixel units. Each pixel unit comprises a thin film transistor. The gate of the thin film transistor is coupled to the scan line, and the source is coupled to the data line, and the drain is coupled to the pixel electrode. However, in the technology, due to the parasitic capacitance existing between the drain and the gate of the thin film transistor, in the moment of deactivating the gate, the change of the gate voltage will pull down the voltage of the pixel electrode. Accordingly, both the common voltage on the common electrode and the gray scale voltage of the pixel electrode change. Accordingly, the bad appearances of afterimage and image flicker of the liquid crystal display device happen during the display.

### SUMMARY OF THE INVENTION

An objective of the present invention is to provide an array substrate, and the array substrate can makes the change of the voltage of the common electrode and the change of the voltage of the pixel electrode consistent as the gate is deactivated, and thus to prevent the bad appearances of afterimage and image flicker of the liquid crystal display device during the display.

The present invention further provides a liquid crystal display device and a drive method of a liquid crystal display device.

For solving the aforesaid technical issue, the technical solution employed by the present invention is:

First, the present invention provides an array substrate, and the array substrate comprises a substrate, and two scan lines, a data line and a common electrode line located on the substrate, and the scan lines and the data line, the common electrode line are located to be isolated and intersect, and form a pixel unit, and the pixel unit comprises a pixel electrode, a common electrode, a first thin film transistor and a second thin film transistor, and both a gate of the first thin film transistor and a gate of the second thin film transistor are coupled to the scan line, and a source of the first thin film transistor is coupled to the data line, and a drain of the first thin film transistor is coupled to the pixel electrode, and a source of the second thin film transistor is coupled to the common electrode line, and a drain of the second thin film transistor is coupled to common electrode, and the second thin film transistor and the first thin film transistor are the same.

The gate of the first thin film transistor and the gate of the second thin film transistor in the pixel unit are coupled to the two scan lines which are different and adjacent.

The gate of the first thin film transistor and the gate of the second thin film transistor in the pixel unit are coupled to the same scan line.

The array substrate further comprises at least one scan line, and the at least one scan line encloses to be the data line and the common electrode line of the pixel unit.

The data line and the common electrode line are located to be parallel with each other and separated, and the scan lines are parallel with one another, and each pixel unit is enclosed by two adjacent scan lines and one data line, one common electrode line which are isolated and intersect with one another.

Second, the present invention further provides a liquid crystal display device, wherein the liquid crystal display device comprises a data driver, a scan driver and any one of the aforesaid array substrates, and the data driver is coupled to the data line of the array substrate, and the scan driver is coupled to the scan line, and the data driver is employed to provide a gray scale voltage to the pixel electrode, and the scan driver is employed to provide a scan signal to activate or deactivate the gate of the first thin film transistor and the gate of the second thin film transistor.

The liquid crystal display device further comprises a common voltage generation circuit, and the common voltage generation circuit is employed to provide a common voltage to the common electrode.

Third, the present invention provides a drive method of a liquid crystal display device, comprising steps of:

providing a scan signal to a row of scan line coupled to a first thin film transistor, and the row of the scan line activates a gate of the first thin film transistor;

providing a gray scale voltage to a column of data line corresponding to the row of the scan line, and the gray scale voltage charges a corresponding pixel electrode through a source and a drain of the first thin film transistor;

providing the scan signal to a next row of scan line, and the row of the scan line is coupled to a second thin film transistor, and the scan signal activates a gate of the second thin film transistor; providing a common voltage to a common electrode line corresponding to the row of the scan line, and the common electrode line charges a corresponding common electrode through a source and a drain of the second thin film transistor; the second thin film transistor and the first thin film transistor are the same.

Forth, the present invention provides another drive method of a liquid crystal display device, comprising steps of:

providing a scan signal to a row of scan line to activate a gate of a first thin film transistor and a gate of a second thin film transistor coupled to the row of the scan line, wherein the second thin film transistor and the first thin film transistor are the same;

providing a gray scale voltage to a column of data line corresponding to the row of the scan line, and the gray scale voltage charges a corresponding pixel electrode through a source and a drain of the first thin film transistor;

providing a common voltage to a common electrode line corresponding to the row of the scan line, and the common electrode line charges a corresponding common electrode through a source and a drain of the second thin film transistor.

Compared with prior art, the technical solution of the present invention at least possesses benefits below:

In the technical solution of the present invention, each pixel unit comprises a first thin film transistor and a second thin film transistor, and both a gate of the first thin film transistor and a gate of the second thin film transistor are coupled to the scan line, and a source of the first thin film transistor is coupled to the data line, and a drain of the first thin film transistor is coupled to the pixel electrode, and a source of the second thin film transistor is coupled to the common electrode line, and a drain of the second thin film transistor is coupled to common electrode. Therefore, the pixel electrode is charged through the first thin film transistor, and the common electrode is charged through the second thin film transistor.

Moreover, because the second thin film transistor and the first thin film transistor are the same, the parasitic capacitance existing between the drain and the gate of the second thin film transistor coupled to the common electrode and the parasitic capacitance existing between the drain and the gate of the first thin film transistor coupled to the pixel electrode are consistent. Thus, in the moment of deactivating the gate, the change of the common voltage of the common electrode and the change of the gray scale voltage are consistent to prevent the bad appearances of afterimage and image flicker of the liquid crystal display device during the display.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other variations according to these figures without paying the premise.

FIG. 1 is a structure diagram of an array substrate in the embodiment of the present invention;

FIG. 2 is a structure diagram of the array substrate corresponding to the I portion in FIG. 1 in the first embodiment of the present invention; and

FIG. 3 is a structure diagram of the array substrate corresponding to the I portion in FIG. 1 in the second embodiment of the present invention.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

Besides, the following descriptions for the respective embodiments are specific embodiments capable of being implemented for illustrations of the present invention with referring to appended figures. For example, the terms of up, down, front, rear, left, right, interior, exterior, side, etcetera are merely directions of referring to appended figures. Therefore, the wordings of directions are employed for explaining and understanding the present invention but not limitations thereto.

In the description of the invention, which needs explanation is that the term “installation”, “connected”, “connection” should be broadly understood unless those are clearly defined and limited, otherwise, For example, those can be a fixed connection, a detachable connection, or an integral connection; those can be a mechanical connection, or an electrical connection; those can be a direct connection, or an indirect connection with an intermediary, which may be an internal connection of two elements. To those of ordinary skill in the art, the specific meaning of the above terminology in the present invention can be understood in the specific circumstances.

Besides, in the description of the present invention, unless with being indicated otherwise, “plurality” means two or more. In the present specification, the term “process” encompasses an independent process, as well as a process that cannot be clearly distinguished from another process but yet achieves the expected effect of the process of interest. Moreover, in the present specification, any numerical range expressed herein using “to” refers to a range including the numerical values before and after “to” as the minimum and maximum values, respectively. In figures, the same reference numbers will be used to refer to the same or like parts.

In the embodiment of the present invention, the array substrate comprises a substrate, and two scan lines, a data line and a common electrode line located on the substrate, and the scan lines and the data line, the common electrode line are located to be isolated and intersect, and form a pixel unit, and the pixel unit comprises a pixel electrode, a common electrode, a first thin film transistor and a second thin film transistor, and both a gate of the first thin film transistor and a gate of the second thin film transistor are coupled to the scan line, and a source of the first thin film transistor is coupled to the data line, and a drain of the first thin film transistor is coupled to the pixel electrode, and a source of the second thin film transistor is coupled to the common electrode line, and a drain of the second thin film transistor is coupled to common electrode, and the second thin film transistor and the first thin film transistor are the same.

In the embodiment of the present invention, the array substrate further comprises at least one scan line, and the at least one scan line encloses to be the data line and the common electrode line of the pixel unit. Namely, the array substrate comprises a substrate and a plurality of scan lines, a plurality of data lines and a plurality of common electrode lines located on the substrate, wherein the scan lines and the data lines, the common electrode lines are located to be isolated and intersect, and form a plurality of pixel units.

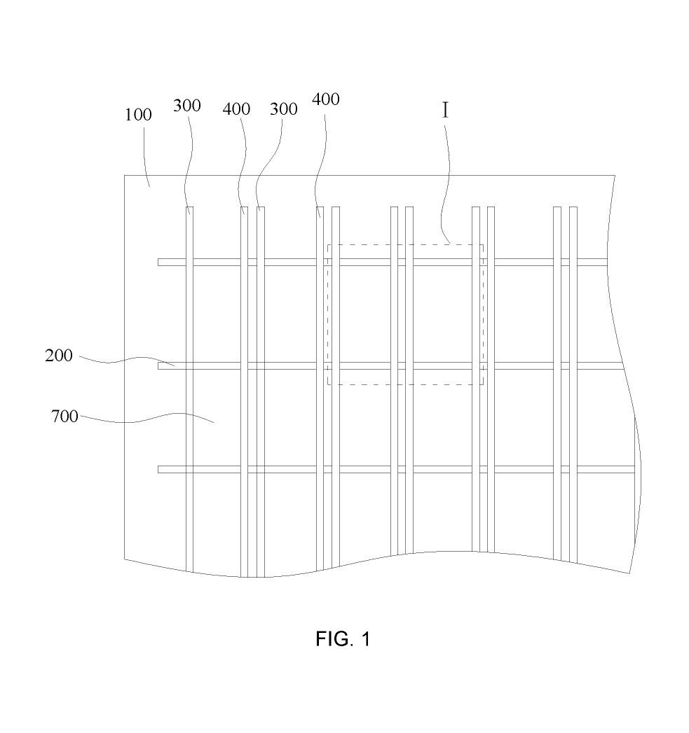

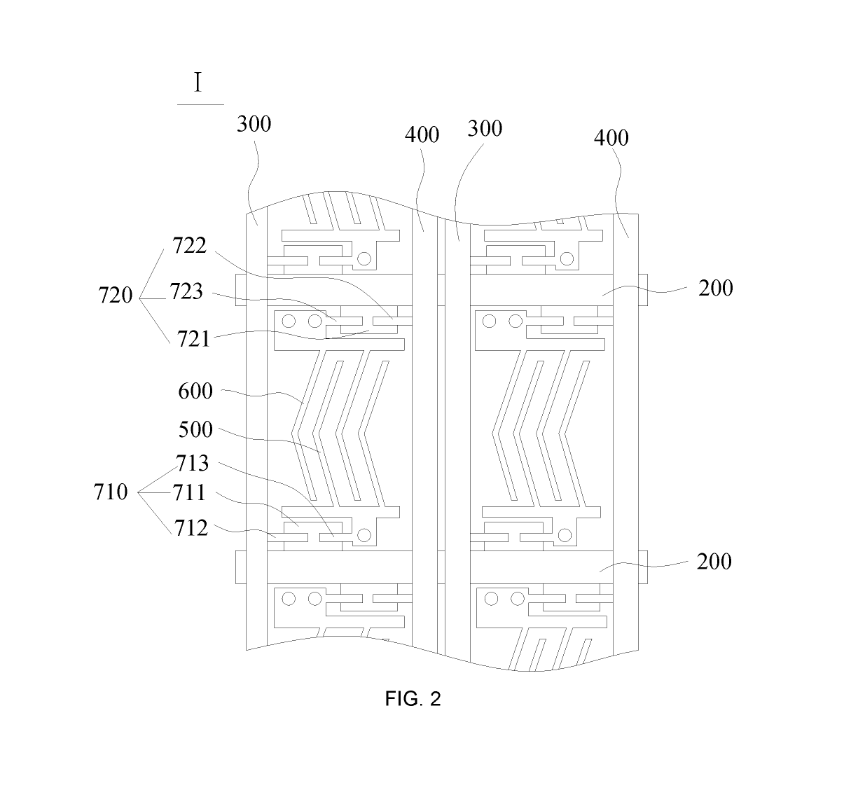

Please refer to FIG. 1 and FIG. 2. FIG. 1 is a structure diagram of an array substrate in the embodiment of the present invention. FIG. 2 is a structure diagram of the array substrate corresponding to the I portion in FIG. 1 in the first embodiment of the present invention. In the first embodiment of the present invention, the array substrate comprises a substrate 100 and a plurality of scan lines 200, a plurality of data lines 300 and a plurality of common electrode lines 400 located on the substrate 100. In this embodiment, the plurality of scan lines 200 are parallel with one another. The data lines 300 and the common electrode lines 400 are located in the same direction. Preferably, the data lines 300 and the common electrode lines 400 are parallel with one another. The scan lines 200 and the data lines 300, the common electrode lines 400 are located to be isolated and intersect, and form a plurality of pixel units 700. Specifically, each pixel unit 700 is enclosed by two adjacent scan lines 200 and one data line 300, one common electrode line 400 which are isolated and intersect with one another. Namely, the two adjacent scan lines 200 cross the one data line 300 and the one common electrode line 400. The formed enclosed quadrangle is the pixel unit 700.

Each pixel unit 700 comprises a pixel electrode 500, a common electrode 600, a first thin film transistor 710 and a second thin film transistor 720. The first thin film transistor 710 comprises a gate 711, a source 712 and a drain 713. The second thin film transistor 720 comprises a gate 721, a source 722 and a drain 723. Both the gate 711 of the first thin film transistor 710 and the gate 721 of the second thin film transistor 720 are coupled to the scan line 200 in the same pixel unit 700. The source 712 of the first thin film transistor 710 is coupled to the data line 300, and the drain 713 of the first thin film transistor 710 is coupled to the pixel electrode 500. The source 722 of the second thin film transistor 720 is coupled to the common electrode line 400, and the drain 723 of the second thin film transistor 720 is coupled to common electrode 600. The second thin film transistor 720 and the first thin film transistor 710 are the same. Specifically, structures of the second thin film transistor 720 and the first thin film transistor 710 are the same.

The common electrode 600 comprises a plurality of sub common electrodes (not indicated with number in figure), and the pixel electrode 500 comprises a plurality of sub pixel electrodes (not indicated with number in figure), and each sub common electrode corresponds to one sub pixel electrode, i.e. the corresponding relationship of the sub common electrode and the sub pixel electrode is one to one. The extension direction of the sub common electrode can be parallel with the extension direction of the sub pixel electrode. An electrical field is formed between the common electrode 600 and the pixel electrode 500.

In this embodiment, the gate 711 of the first thin film transistor 710 and the gate 721 of the second thin film transistor 720 in each pixel unit 700 are coupled to the two scan lines 200 which are different and adjacent. For instance, in the pixel unit 700 formed by the nth scan line 200, the n+1th scan line 200, the nth data line 300 and the nth common electrode line 400 which are isolated and intersect, the gate 711 of the first thin film transistor 710 is coupled to the nth scan line 200, and the gate 721 of the second thin film transistor 720 is coupled to the n+1th scan line 200, and the source 712 of the first thin film transistor 710 is coupled to the nth data line 300, and the source 722 of the second thin film transistor 720 is coupled to the nth common electrode line 400, wherein n is a nature number.

The scan driver (not shown in the figure) of the liquid crystal display device outputs the scan signal. As the scan signal is transmitted to the gate 711 of the first thin film transistor 710 through the nth scan line 200, the gate 711 of the first thin film transistor 710 coupled with the nth scan line 200 is activated. Then, the nth data line 300 transmits the gray scale voltage outputted by the data driver (not shown in the figure) of the liquid crystal display device to the source 712 of the first thin film transistor 710, and to transmits the gray scale voltage to the pixel electrode 500 coupled with the drain 713 through the source 712 and the drain 713 of the first thin film transistor 710 to charge the pixel electrode 500.

Meanwhile, the scan driver of the liquid crystal display device outputs the scan signal to the n+1th scan line 200. The scan signal activates the gate 721 of the second thin film transistor 720 coupled with the n+1th scan line 200 through the n+1th scan line 200. Then, the common electrode line 400 coupled with the source of the second thin film transistor 720 transmits the common voltage to the common electrode 600 through the source 722 and the drain 723 of the second thin film transistor 720 to charge the common electrode 600.

The voltage on the pixel electrode 500 and the voltage on the common electrode 600 form a difference value, and thus to form an electrical field which makes the liquid crystal respond to show images with the liquid crystal display device.

As the gate 711 of the first thin film transistor 710 is deactivated, due to the parasitic capacitance Cst1 existing between the gate 711 and the drain 713 of the first thin film transistor 710, the voltage on the pixel electrode 500 coupled with the drain 713 is pulled down with ΔVp1. Meanwhile, the gate 721 of the second thin film transistor 720 is deactivated, and due to the parasitic capacitance Cst2 existing between the gate 721 and the drain 723 of the second thin film transistor 720, the voltage on the common electrode 600 coupled with the drain 723 is pulled down with ΔVp2. In this embodiment, because the structure of the first thin film transistor 710 and the structure of the second thin film transistor 720 are the same, the parasitic capacitance Cst1 existing between the gate 711 and the drain 713 of the first thin film transistor 710 is equal to the parasitic capacitance Cst2 existing between the gate 721 and the drain 723 of the second thin film transistor 720. Thus, the voltage pull down value ΔVp2 on the common electrode is equal to the voltage pull down value ΔVp1 on the pixel electrode 500. Accordingly, the bad appearances of afterimage and image flicker caused by that the voltage pull down value ΔVp2 on the common electrode and the voltage pull down value ΔVp1 on the pixel electrode 500 are different.

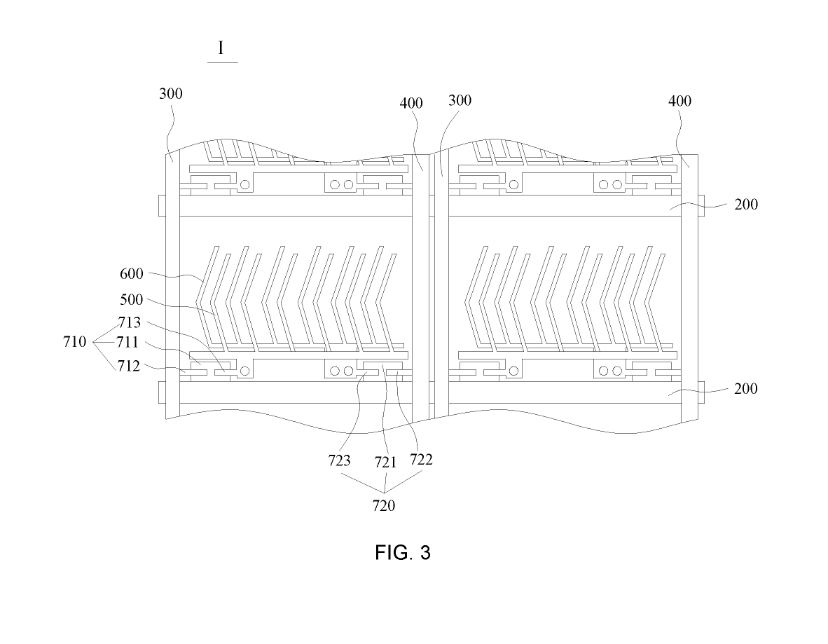

Please refer to FIG. 3. FIG. 3 is a structure diagram of the array substrate corresponding to the I portion in FIG. 1 in the second embodiment of the present invention. The structure of the array substrate in the second embodiment of the present invention is basically the same as the structure of the array substrate in the first embodiment. The difference is: the gate 711 of the first thin film transistor 710 and the gate 721 of the second thin film transistor 720 in each pixel unit 700 of the array substrate in this embodiment (the second embodiment) are coupled to the same scan line 200.

As the scan driver of the liquid crystal display device outputs the scan signal to the nth scan line 200, the scan signal activates the gate 711 of the first thin film transistor 710 and the gate 721 of the second thin film transistor 720 through the nth scan line 200 at the same time. Then, the nth data line 300 transmits the gray scale voltage to the source 712 of the first thin film transistor 710, and to transmits the gray scale voltage to the pixel electrode 500 coupled with the drain 713 through the source 712 and the drain 713 of the first thin film transistor 710 to charge the pixel electrode 500; the common electrode line 400 coupled with the source of the second thin film transistor 720 transmits the common voltage to the common electrode 600 through the source 722 and the drain 723 of the second thin film transistor 720 to charge the common electrode 600.

The voltage on the pixel electrode 500 and the voltage on the common electrode 600 form a difference value, and thus to form an electrical field which makes the liquid crystal respond to show images with the liquid crystal display device.

As the gate 711 of the first thin film transistor 710 is deactivated, due to the parasitic capacitance Cst1 existing between the gate 711 and the drain 713 of the first thin film transistor 710, the voltage on the pixel electrode 500 coupled with the drain 713 is pulled down with ΔVp1. Meanwhile, the gate 721 of the second thin film transistor 720 is deactivated, and due to the parasitic capacitance Cst2 existing between the gate 721 and the drain 723 of the second thin film transistor 720, the voltage on the common electrode 600 coupled with the drain 723 is pulled down with ΔVp2. In this embodiment, because the structure of the first thin film transistor 710 and the structure of the second thin film transistor 720 are the same, the parasitic capacitance Cst1 existing between the gate 711 and the drain 713 of the first thin film transistor 710 is equal to the parasitic capacitance Cst2 existing between the gate 721 and the drain 723 of the second thin film transistor 720. Thus, the voltage pull down value ΔVp2 on the common electrode is equal to the voltage pull down value ΔVp1 on the pixel electrode 500. Accordingly, the bad appearances of afterimage and image flicker caused by that the voltage pull down value ΔVp2 on the common electrode and the voltage pull down value ΔVp1 on the pixel electrode 500 are different.

The present invention further provides a liquid crystal display device. The liquid crystal display device comprises a data driver, a scan driver and any array substrate of the aforesaid embodiments or implementations. The data driver is coupled to the data line on the array substrate, and the scan driver is coupled to the scan line, and the data driver is employed to provide a gray scale voltage to the pixel electrode, and the scan driver is employed to send a scan signal to activate or deactivate the gate of the first thin film transistor and the gate of the second thin film transistor. The liquid crystal display device further comprises a common voltage generation circuit, and the common voltage generation circuit is employed to provide a common voltage to the common electrode.

The embodiment of the present invention further provides another drive method of a liquid crystal display device, and the drive method of the liquid crystal display device comprises steps of:

providing a scan signal to a row of scan line coupled to a first thin film transistor, and the row of the scan line activates a gate of the first thin film transistor;

providing a gray scale voltage to a column of data line corresponding to the row of the scan line, and the gray scale voltage charges a corresponding pixel electrode through a source and a drain of the first thin film transistor;

providing the scan signal to a next row of scan line, and the row of the scan line is coupled to a second thin film transistor, and the scan signal activates a gate of the second thin film transistor; providing a common voltage to a common electrode line corresponding to the row of the scan line, and the common electrode line charges a corresponding common electrode through a source and a drain of the second thin film transistor; the second thin film transistor and the first thin film transistor are the same.

The voltage on the pixel electrode and the voltage on the common electrode form a difference value, and thus to form an electrical field which makes the liquid crystal respond to show images with the liquid crystal display device.

As the gate of the first thin film transistor is deactivated, due to the parasitic capacitance existing between the gate and the drain of the first thin film transistor, the voltage on the pixel electrode coupled with the drain is pulled down. Meanwhile, the gate of the second thin film transistor is deactivated, and due to the parasitic capacitance existing between the gate and the drain of the second thin film transistor, the voltage on the common electrode coupled with the drain is pulled down. In this embodiment, because the structure of the first thin film transistor and the structure of the second thin film transistor are the same, the parasitic capacitance existing between the gate and the drain of the first thin film transistor is equal to the parasitic capacitance existing between the gate and the drain of the second thin film transistor. Thus, the voltage pull down value on the common electrode is equal to the voltage pull down value on the pixel electrode. Accordingly, the bad appearances of afterimage and image flicker caused by that the voltage pull down value on the common electrode and the voltage pull down value on the pixel electrode are different.

The embodiment of the present invention further provides another drive method of a liquid crystal display device, and the drive method of the liquid crystal display device comprises steps of:

providing a scan signal to a row of scan line to activate a gate of a first thin film transistor and a gate of a second thin film transistor coupled to the row of the scan line, and the second thin film transistor and the first thin film transistor are the same;

providing a gray scale voltage to a column of data line corresponding to the row of the scan line, and the gray scale voltage charges a corresponding pixel electrode through a source and a drain of the first thin film transistor;

providing a common voltage to a common electrode line corresponding to the row of the scan line, and the common electrode line charges a corresponding common electrode through a source and a drain of the second thin film transistor.

The voltage on the pixel electrode and the voltage on the common electrode form a difference value, and thus to form an electrical field which makes the liquid crystal of the liquid crystal display device respond to show images with the liquid crystal display device.

As the gate of the first thin film transistor is deactivated, due to the parasitic capacitance existing between the gate and the drain of the first thin film transistor, the voltage on the pixel electrode coupled with the drain is pulled down. Meanwhile, the gate of the second thin film transistor is deactivated, and due to the parasitic capacitance existing between the gate and the drain of the second thin film transistor, the voltage on the common electrode coupled with the drain is pulled down. In this embodiment, because the structure of the first thin film transistor and the structure of the second thin film transistor are the same, the parasitic capacitance existing between the gate and the drain of the first thin film transistor is equal to the parasitic capacitance existing between the gate and the drain of the second thin film transistor. Thus, the voltage pull down value on the common electrode is equal to the voltage pull down value on the pixel electrode. Accordingly, the bad appearances of afterimage and image flicker caused by that the voltage pull down value on the common electrode and the voltage pull down value on the pixel electrode are different.

In the description of the present specification, the reference terms, “one embodiment”, “some embodiments”, “an illustrative embodiment”, “an example”, “a specific example”, or “some examples” mean that such description combined with the specific features of the described embodiments or examples, structure, material, or characteristic is included in the utility model of at least one embodiment or example. In the present specification, the terms of the above schematic representation do not certainly refer to the same embodiment or example. Meanwhile, the particular features, structures, materials, or characteristics which are described may be combined in a suitable manner in any one or more embodiments or examples.

Above are embodiments of the present invention, which does not limit the scope of the present invention. Any modifications, equivalent replacements or improvements within the spirit and principles of the embodiment described above should be covered by the protected scope of the invention.

1. An array substrate, and the array substrate comprises a substrate, and two scan lines, a data line and a common electrode line located on the substrate, wherein the scan lines and the data line, the common electrode line are located to be isolated and intersect, and form a pixel unit, and the pixel unit comprises a pixel electrode, a common electrode, a first thin film transistor and a second thin film transistor, and both a gate of the first thin film transistor and a gate of the second thin film transistor are coupled to the scan line, and a source of the first thin film transistor is coupled to the data line, and a drain of the first thin film transistor is coupled to the pixel electrode, and a source of the second thin film transistor is coupled to the common electrode line, and a drain of the second thin film transistor is coupled to common electrode, and the second thin film transistor and the first thin film transistor are the same.

2. The array substrate according to claim 1, wherein the gate of the first thin film transistor and the gate of the second thin film transistor in the pixel unit are coupled to the two scan lines which are different and adjacent.

3. The array substrate according to claim 1, wherein the gate of the first thin film transistor and the gate of the second thin film transistor in the pixel unit are coupled to the same scan line.

4. The array substrate according to claim 1, wherein the array substrate further comprises at least one scan line, and the at least one scan line encloses to be the data line and the common electrode line of the pixel unit.

5. The array substrate according to claim 2, wherein the array substrate further comprises at least one scan line, and the at least one scan line encloses to be the data line and the common electrode line of the pixel unit.

6. The array substrate according to claim 3, wherein the array substrate further comprises at least one scan line, and the at least one scan line encloses to be the data line and the common electrode line of the pixel unit.

7. The array substrate according to claim 4, wherein the data line and the common electrode line are located to be parallel with each other and separated, and the scan lines are parallel with one another, and each pixel unit is enclosed by two adjacent scan lines and one data line, one common electrode line which are isolated and intersect with one another.

8. The array substrate according to claim 5, wherein the data line and the common electrode line are located to be parallel with each other and separated, and the scan lines are parallel with one another, and each pixel unit is enclosed by two adjacent scan lines and one data line, one common electrode line which are isolated and intersect with one another.

9. The array substrate according to claim 6, wherein the data line and the common electrode line are located to be parallel with each other and separated, and the scan lines are parallel with one another, and each pixel unit is enclosed by two adjacent scan lines and one data line, one common electrode line which are isolated and intersect with one another.

10. A liquid crystal display device, wherein the liquid crystal display device comprises a data driver, a scan driver and an array substrate, and the array substrate comprises a substrate, and two scan lines, a data line and a common electrode line located on the substrate, wherein the scan lines and the data line, the common electrode line are located to be isolated and intersect, and form a pixel unit, and the pixel unit comprises a pixel electrode, a common electrode, a first thin film transistor and a second thin film transistor, and both a gate of the first thin film transistor and a gate of the second thin film transistor are coupled to the scan line, and a source of the first thin film transistor is coupled to the data line, and a drain of the first thin film transistor is coupled to the pixel electrode, and a source of the second thin film transistor is coupled to the common electrode line, and a drain of the second thin film transistor is coupled to common electrode, and the second thin film transistor and the first thin film transistor are the same; the data driver is coupled to the data line of the array substrate, and the scan driver is coupled to the scan line, and the data driver is employed to provide a gray scale voltage to the pixel electrode, and the scan driver is employed to provide a scan signal to activate or deactivate the gate of the first thin film transistor and the gate of the second thin film transistor.

11. The liquid crystal display device according to claim 10, wherein the gate of the first thin film transistor and the gate of the second thin film transistor in the pixel unit are coupled to the two scan lines which are different and adjacent.

12. The liquid crystal display device according to claim 10, wherein the gate of the first thin film transistor and the gate of the second thin film transistor in the pixel unit are coupled to the same scan line.

13. The liquid crystal display device according to claim 10, wherein the array substrate further comprises at least one scan line, and the at least one scan line encloses to be the data line and the common electrode line of the pixel unit.

14. The liquid crystal display device according to claim 11, wherein the array substrate further comprises at least one scan line, and the at least one scan line encloses to be the data line and the common electrode line of the pixel unit.

15. The liquid crystal display device according to claim 12, wherein the array substrate further comprises at least one scan line, and the at least one scan line encloses to be the data line and the common electrode line of the pixel unit.

16. The liquid crystal display device according to claim 13, wherein the data line and the common electrode line are located to be parallel with each other and separated, and the scan lines are parallel with one another, and each pixel unit is enclosed by two adjacent scan lines and one data line, one common electrode line which are isolated and intersect with one another.

17. The liquid crystal display device according to claim 10, wherein the liquid crystal display device further comprises a common voltage generation circuit, and the common voltage generation circuit is employed to provide a common voltage to the common electrode.

18. The liquid crystal display device according to claim 16, wherein the liquid crystal display device further comprises a common voltage generation circuit, and the common voltage generation circuit is employed to provide a common voltage to the common electrode.

19. A drive method of a liquid crystal display device, comprising steps of:
providing a scan signal to a row of scan line coupled to a first thin film transistor, and the row of the scan line activates a gate of the first thin film transistor;
providing a gray scale voltage to a column of data line corresponding to the row of the scan line, and the gray scale voltage charges a corresponding pixel electrode through a source and a drain of the first thin film transistor;
providing the scan signal to a next row of scan line, and the row of the scan line is coupled to a second thin film transistor, and the scan signal activates a gate of the second thin film transistor; providing a common voltage to a common electrode line corresponding to the row of the scan line, and the common electrode line charges a corresponding common electrode through a source and a drain of the second thin film transistor; the second thin film transistor and the first thin film transistor are the same.

20. (canceled)
